(19) United States
(12) Patent Application Publication
(10) Pub. No.: US 2023/0400536 A1
(43) Pub. Date: Dec. 14, 2023

(54) Chopped Hall Sensor and Method for Measuring at Least One Hall Voltage

(71) Applicant: TDK-Micrones GmbH, Freiburg im Breisgau (DE)

(72) Inventors: Roberto Rivoir, Neuf-Brisach (FR); David Muthers, Denzlingen (DE)

(21) Appl. No.: 18/208,574

(22) Filed: Jun. 12, 2023

(30) Foreign Application Priority Data
Jun. 13, 2022 (DE) 10 2022 114 766.5

(51) Int. Cl. G01R 33/07

(52) U.S. Cl. CPC G01R 33/072

(57) ABSTRACT

In a method for measuring a Hall voltage, a Hall sensor element is made available, which includes a plurality of connection pairs for imprinting a supply current or applying a supply voltage and for capturing detection signals. The method has the following steps:
imprinting the supply current onto the Hall sensor element or applying the supply voltage to the Hall sensor element, in such a manner that the supply current flows from the first to the second connector of one of the connection pairs for a predetermined period of time;
while imprinting the supply current or applying the supply voltage, capturing a detection signal between the first and the second connector of a further connection pair of the Hall sensor element;
repeating steps a) and b) once or multiple times, using connection pairs and/or connectors that are interchanged according to an orthogonal switching principle or a spin current principle, once or multiple times, so as to capture at least one further detection signal, wherein in at least one of the repetitions, the predetermined time period is changed, and the steps in step a) and b) are repeated with the changed time period,
determining the Hall voltage from the detection signals.

### CROSS-REFERENCE TO RELATED APPLICATIONS

This application claims priority to German Patent Application No. 10 2022 114 766.5 filed Jun. 13, 2022, the disclosure of which is hereby incorporated by reference in its entirety.

### BACKGROUND OF THE INVENTION

### Field of the Invention

The invention relates to a method as described herein and a method as described herein. Furthermore, the invention relates to a chopped Hall sensor as described herein, as well as to a chopped Hall sensor as described herein.

### Description of Related Art

Hall sensors are magnetic-field sensors that are based on the Hall effect named for the physicist Edwin Hall. The Hall effect occurs when the electrons of a supply current move through a Hall sensor in a transverse magnetic field. By means of the Lorentz force that acts on the electrons, an electric field forms transverse to the current direction, which field corresponds to an electric voltage that is referred to as a Hall voltage.

Hall sensors are usually produced from a semiconductor material. However, due to tolerances that occur during production and during assembly, mechanical stresses can occur in the semiconductor material, which stresses can cause undesirable offset voltages that are superimposed on the Hall voltage. This is disadvantageous, in particular, in the case of low Hall voltages.

For compensation of offset voltages, it is known to use what is called the quadrature shift or the spin Hall shift. Hall sensors in which these methods are used are also referred to as chopped Hall sensors.

In the case of chopped Hall sensors, the direction of the supply current is periodically changed by means of a Hall sensor element. As a result, the direction, i.e., the prefix of the offset voltages also changes. By means of an addition of the detection signals of a chopped Hall sensor, the offset voltages can be removed from the actual measurement signal, at least ideally.

A method and a chopped Hall sensor of the type stated initially are known from DE 102 02 427 B4. The Hall sensor element of this chopped Hall sensor has different connection pairs that are periodically connected, at a predetermined switching frequency, to a current or voltage supply source, using a switching device, so as to imprint supply currents in different directions onto the Hall sensor element. For every imprinted supply current, a detection signal, in each instance, is captured for the electric voltage that occurs transverse to the supply current at the Hall sensor element, and the detection signals are added up or averaged.

Although the previously known method and the previously known chopped Hall sensor have proven themselves in practice, they nevertheless need improvement. For example, Hall sensor elements have only a comparatively low measurement sensitivity, which amounts to approximately 50 μV//(mT·V) in the case of Hall sensor elements that are integrated into a silicon substrate. The resulting low Hall voltages are susceptible, in particular in the case of chopped Hall sensors, in which the Hall sensor element is arranged at a certain distance from the current supply source or voltage supply source, to electromagnetic interference in the surroundings of the Hall sensor element. This is because the electrical lines by way of which the connection pairs of the Hall sensor element are connected, during operation of the chopped Hall sensor, to the signal connectors, for capturing the detection signals, act like antennas that receive electromagnetic interference in the surroundings of the Hall sensor element, and can be superimposed on the detection signals. Furthermore, the supply current that flows in the electric lines also emits electromagnetic interference when the flow direction is changed, and this can impair electronic circuits situated in the vicinity of the chopped Hall sensor.

### SUMMARY OF THE INVENTION

The task therefore exists of creating a method of the type stated initially and a chopped Hall sensor of the type stated initially, which method and sensor allow reliable and low-interference measurement of the Hall voltage even if electromagnetic interference occurs in the surroundings of the at least one Hall sensor element. Furthermore, when carrying out the method and during operation of the chopped Hall sensor, only comparatively slight electromagnetic emissions should be emitted into the environment by the method or by the chopped Hall sensor itself.

According to the invention, this task is accomplished, with regard to the method, using the characteristics as described herein. These characteristics provide for the following steps, in the case of a method for measuring at least one Hall voltage, in which method at least one Hall sensor element is made available, which element comprises a plurality of connection pairs for imprinting a supply current or applying a supply voltage and for capturing detection signals:
a) imprinting the supply current onto the Hall sensor element or applying the supply voltage to the Hall sensor element, in such a manner that the supply current flows from the first to the second connector of one of the connection pairs for a predetermined period of time;
b) while imprinting the supply current or applying the supply voltage, capturing a detection signal between the first and the second connector of a further connection pair of the Hall sensor element;
c) repeating steps a) and b) once or multiple times, using connection pairs and/or connectors that are interchanged according to an orthogonal switching principle or a spin current principle, once or multiple times, so as to capture at least one further detection signal,
d) determining the Hall voltage from the detection signals, and
e) if necessary, repeating steps a) to d) and, if applicable, e),

wherein the predetermined time period is changed, at least in one of the repetitions mentioned in step c), and the steps mentioned in step c) are repeated with the changed period of time.

If the sequence of the steps with the changed time periods is considered in the frequency domain, spreading (widening) of the characteristic spectrum takes place. The previously fixed, narrow-band (discrete) frequencies, i.e., their amplitudes, become smaller and more broad-band, in a spectral view, if only a slight variation of the time periods takes place. In this case, one also speaks of “jitter” or “jittering,” which changes the spectral characteristics in a way that is advantageous for robust operation. More comprehensive and non-periodic variation of the individual time periods finally leads to complete widening of the spectrum, and discrete individual frequencies disappear almost completely. The characteristic makes a transition into continuous noise, with clearly reduced amplitudes.

With regard to the chopped Hall sensor, the task stated above is accomplished with the characteristics as described herein. These characteristics provide that the chopped Hall sensor has at least one Hall sensor element that has a plurality of connection pairs for imprinting a supply current and for capturing detection signals, that the chopped Hall sensor has a control and evaluation apparatus for the Hall sensor element, which has
at least one current or voltage supply source for generating the supply current,
a switching device, and
a control device, which has a pulse generator, for the switching device, that the switching device has
connection contact pairs that are connected to the connection pairs of the Hall sensor element by way of electric lines,
supply connectors that are connected to the current or voltage supply source, and
signal connectors for capturing the detection signals, that the switching device, the control device, and the pulse generator are configured for carrying out the following steps:
a) for a predetermined period of time, connecting a connection pair of the Hall sensor element to the supply connectors, so as to imprint a supply current onto the Hall sensor element, which current flows from the first to the second connector of the connection pair,
b) connecting a further connection pair of the Hall sensor element to the signal connectors, so as to capture a detection signal that is applied between the first and the second connector of the further connection pair during imprinting of the supply current onto das Hall sensor element;
c) repeating steps a) and b) once or multiple times, using connection pairs and/or connectors that are interchanged according to an orthogonal switching principle or a spin current principle, once or multiple times, so as to capture at least one further detection signal, and
d) determining the Hall voltage from the detection signals,

and that the switching device, the control device, and the pulse generator are configured in such a manner that during at least one of the repetitions mentioned in step c), the predetermined time period is changed, and used during the repetition of steps a) and b).

In an advantageous manner, the frequency bands of the feed currents fed into the at least one Hall sensor element by means of the connection pairs and the detection signals captured at the connection pairs are spread over a broader frequency range by means of changing the predetermined time period while carrying out the method. If frequency-discrete electromagnetic interference and/or electromagnetic interference occurs, which relates to only part of the broader frequency range, the feed currents and the detection signals can thereby be transmitted without interference, to the greatest possible extent, in the remaining frequency range that is not affected by the electromagnetic interference. Individual detection signals that are distorted by electromagnetic interference (outliers) can be identified, if necessary, using known methods of signal processing, and filtered out of the detection signals in such a manner that the Hall voltage is determined solely from the remaining detection signals, which are essentially not affected by interference. The method is preferably carried out in such a manner that a different time period is used during every spin Hall phase that consists of steps a) to d). The method thereby makes particularly effective suppression of electromagnetic interference possible.

By means of changing the time period during which the supply current is fed into the individual connection pairs of the Hall sensor element, in each instance, it is furthermore prevented that when carrying out the method, i.e., during operation of the chopped Hall sensor, electromagnetic interference having a fixed frequency is generated, which could be coupled into a sensitive electronic circuit situated in the vicinity of the chopped Hall sensor, and disrupt its function.

It is also possible, in the case of spin Hall phases, during which the supply current flows through the Hall sensor element in opposite directions (rotation of the supply current by 180° or interchange of the connectors of a connection pair), to use the same predetermined time period, in each instance, and to select this time period differently for every connection pair to which the supply current is supplied or to which the supply voltage is applied.

The task stated above is also accomplished, with regard to the method, using the characteristics as described herein. These characteristics, in the case of a method for measuring at least one Hall voltage, in which at least one Hall sensor element is made available, which comprises a plurality of connection pairs for imprinting a supply current or applying a supply voltage and for capturing detection signals, provide for the following steps:
a) imprinting the supply current onto the Hall sensor element or applying the supply voltage to the Hall sensor element, in such a manner that the supply current flows from the first to the second connector of one of the connection pairs for a predetermined period of time;
b) while imprinting the supply current or applying the supply voltage, capturing a detection signal between the first and the second connector of a further connection pair of the Hall sensor element;
c) repeating steps a) and b) once or multiple times, using connection pairs and/or connectors that are interchanged according to an orthogonal switching principle or a spin current principle, once or multiple times, so as to capture at least one further detection signal;
d) determining the Hall voltage from the detection signals,
e) changing the predetermined time period and repeating steps a) to d) with the changed time period, and, if applicable, repeating step e).

The task mentioned above is also accomplished, with regard to the chopped Hall sensor, using the characteristics as described herein. These characteristics provide that the chopped Hall sensor has at least one Hall sensor element that has a plurality of connection pairs for imprinting a supply current and for capturing detection signals, that the chopped Hall sensor has a control and evaluation apparatus for the Hall sensor element, which has
at least one current or voltage supply source for generating the supply current,
a switching device, and
a control device, having an pulse generator, for the switching device,

wherein the switching device has
connection contact pairs that are connected to the connection pairs of the Hall sensor element by way of electric lines,
supply connectors that are connected to the current or voltage supply source, and
signal connectors for capturing the detection signals,

and wherein the switching device, the control device and the pulse generator are configured for carrying out the following steps:
a) for a predetermined period of time, connecting a connection pair of the Hall sensor element to the supply connectors, so as to imprint the supply current onto the Hall sensor element, which current flows from the first to the second connector of the connection pair,
b) connecting a further connection pair of the Hall sensor element to the signal connectors, so as to capture a detection signal that is present between the first and the second connector of the further connection pair, during imprinting of the supply current onto the Hall sensor element;
c) repeating steps a) and b) once or multiple times, using connection pairs and/or connectors that are interchanged according to an orthogonal switching principle or a spin current principle, once or multiple times, so as to capture at least one further detection signal;
d) determining the Hall voltage from the detection signals;
e) repeating steps a) to d) and, if applicable, e),

and that the switching device, the control device and the pulse generator are configured for changing the predetermined time period in step e) and for repeating the steps mentioned in step e), with the changed time period.

In the case of these solutions, multiple spin Hall cycles are therefore undergone, wherein the predetermined time period is kept constant, in each instance, within the spin Hall cycles, and changed between the spin Hall cycles. In this way, too, the frequency range of the supply currents fed into the at least one Hall sensor element by means of the connection pairs and of the detection signals captured at the connection pairs is changed in such a manner that it is spread over a broader frequency range. Thereby measurement of the Hall voltage, free of interference, to the greatest possible extent, is also made possible using the method as described herein. Furthermore, it is prevented that electromagnetic interference having a fixed frequency is emitted by switching the supply current over.

Advantageous embodiments of the invention are described herein.

In a preferred embodiment of the invention, the Hall sensor element is arranged in an environment in which at least one electromagnetic signal is present, which has at least one discrete interference frequency that causes electromagnetic interference at the detection signals, and/or comprises at least one frequency band that causes electromagnetic interference at the detection signals. In this regard, the predetermined time period is preferably selected and changed in such a manner that the frequency spectrum emitted by the supply current lies outside of the at least one interference frequency and/or outside of the at least one frequency band.

In a practical embodiment of the invention, a cycle signal is generated, and the predetermined time period is set as a function of the period duration of the cycle signal. The method can then be carried out in a simple manner.

In an embodiment of the invention that is particularly easy to carry out, the frequency of the cycle signal is divided by a whole number to change the predetermined time period, in particular by 2ⁿ, wherein n is a whole number that is greater than 1. The predetermined time period can then be derived from the cycle signal, in a simple manner, using a frequency divider.

In another embodiment of the invention, the cycle signal is generated by means of a frequency synthesizer. In this way, it is possible to set the frequency of the cycle signal to almost any desired frequency value while carrying out the method.

It is advantageous if the frequency of the cycle signal is increased or reduced, in each instance, by a predetermined step width, to change the predetermined time period, in such a manner that the frequency of the cycle signal does not exceed a predetermined maximum value and does not drop below a predetermined minimum value. Such a frequency progression, in step shape and with a saw-tooth shape, can be generated, for example, using a frequency synthesizer.

In another advantageous embodiment of the invention, a random signal is generated, and the frequency of the cycle signal, is changed, to change the predetermined time period as a function of the random signal, in such a manner that the frequency of the cycle signal does not exceed a predetermined maximum value and does not drop below a predetermined minimum value. In this regard, the random signal can be a pseudo-random signal or a true random signal. By means of the random change in the frequency of the cycle signal, supply currents fed into the Hall sensor element by way of the electric lines and the exciter voltages passed on to the signal connectors of the switching device by the Hall sensor element, by way of the electric lines, are even better protected against electromagnetic interference. Furthermore, the risk that sensitive electric circuits arranged in the surroundings of the chopped Hall sensor might be impaired due to switching of the switching device is correspondingly reduced.

In a preferred embodiment of the invention, at least one Hall sensor element is integrated into a first semiconductor chip, and the control and evaluation apparatus is integrated into a second semiconductor chip. In this regard, the substrates of the semiconductor chips preferably consist of different semiconductor materials, for example the material of the first semiconductor chip consists of gallium arsenide, and the material of the second semiconductor chip consists of silicon. In the case of a chopped Hall sensor that has multiple Hall sensor elements, multiple first semiconductor chips can also be provided, for example a separate semiconductor chip for every Hall sensor element.

However, it is also conceivable to provide at least one cluster assigned to the control and evaluation apparatus, which cluster has multiple Hall sensor elements integrated into a common first semiconductor chip. If applicable, it is even possible that multiple such clusters are present, which interact with the control and evaluation apparatus and can be integrated into separate semiconductor chips. The Hall sensor elements and/or the clusters can be arranged around the first semiconductor chip that has the control and evaluation apparatus, similar to satellites, and connected to this chip by means of electric lines.

It is advantageous if the signal connectors are connected to the inputs of a measurement amplifier, by way of a filter, and if the filter is configured for blocking at least one discrete frequency and/or at least one frequency band. In this regard, the frequency and/or the frequency band is/are selected in such a manner that the frequencies that occur during operation of the chopped Hall sensor, due to switching of the supply current to the different connection pairs, lie outside of the blocked frequency and/or of the blocked frequency band.

In an advantageous embodiment of the invention, the control device has an output for a control signal, which output stands in a control connection with a frequency control input of the pulse generator, to change the cycle frequency of the pulse generator.

### BRIEF DESCRIPTION OF THE DRAWINGS

In the following, exemplary embodiments of the invention will be explained in greater detail, using the drawing. This shows:

FIG. 1 a block schematic of an exemplary embodiment of a chopped Hall sensor that works according to the spin Hall principle,

FIG. 2 a schematic representation of a Hall sensor element of the chopped Hall sensor, which has four electrical connectors, of which two connectors that lie diagonally opposite one another, in each instance, are assigned to one another in pairs,

FIG. 3 a diagram in which the power spectrum of the electromagnetic signals generated during spin Hall operation of the chopped Hall sensor, by the supply currents fed into the Hall sensor element, are represented by solid lines, and the power spectrum of external electromagnetic signals is represented by dotted lines and cross-hatching, which external signals are present in the surroundings of the chopped Hall sensor, wherein the frequency f is plotted on the abscissa, and the power P is plotted on the ordinate, and

FIG. 4 a block schematic of a further exemplary embodiment of the chopped Hall sensor.

### DESCRIPTION OF THE INVENTION

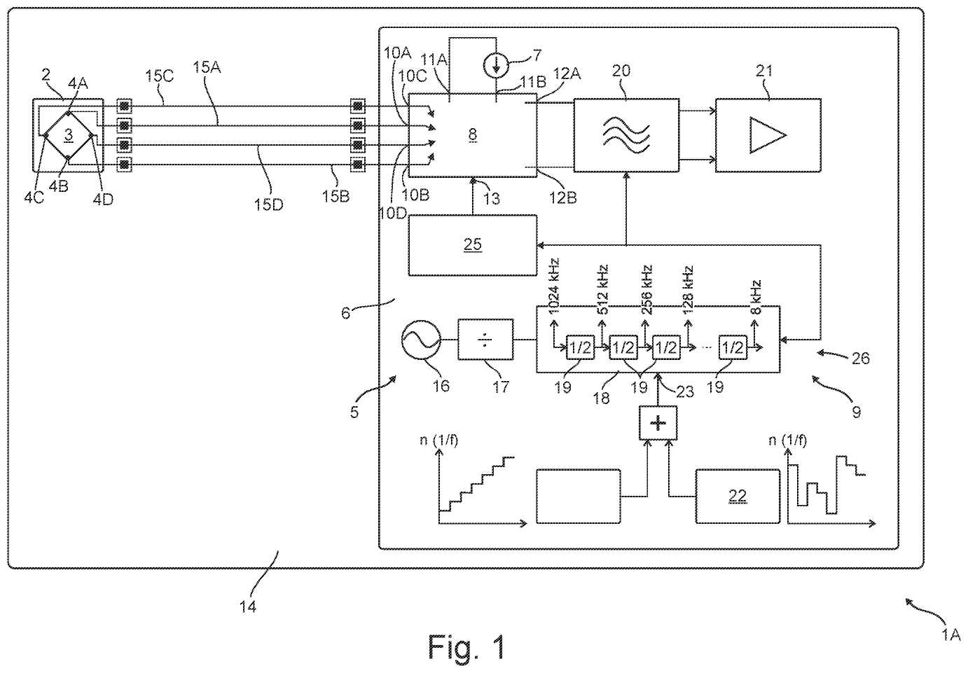

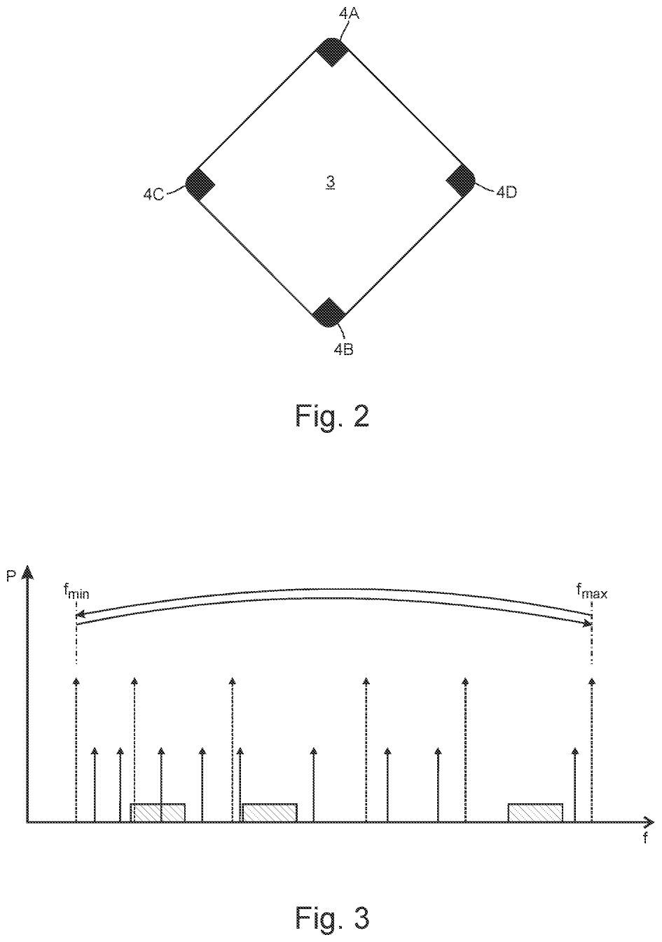

A chopped Hall sensor designated as a whole as 1A in FIG. 1 has a first semiconductor chip 2, into which a plate-shaped Hall sensor element 3 is integrated. The Hall sensor element 3 consists of a semiconductor material, such as, for example, of gallium arsenide, and has, on its edge, multiple connectors 4A, 4B, 4C, 4D spaced apart from one another (FIG. 2), which are offset from one another by 90° with reference to an imaginary center axis that is arranged orthogonal to the plane spanned by the Hall sensor element 3 and runs through a center of symmetry.

The chopped Hall sensor 1A furthermore has a control and evaluation apparatus 5 for das Hall sensor element 3, which is integrated into a second semiconductor chip 6 that is arranged at a distance from the first semiconductor chip 2. The control and evaluation apparatus 5 has a current or voltage supply source 7 for feeding a supply current into the Hall sensor element 3, i.e., applying a supply voltage to the Hall sensor element 3, a switching device 8, and a control device 9 for the switching device 8. The switching device 8 has connection contacts 10A, 10B, 10C, 10D, which are connected, in each instance, to a connector 4A, 4B, 4C, 4D of the Hall sensor element 3, supply connectors 11A, 11B, which are connected to connectors of the current or voltage supply source 8, signal connectors 12A, 12B for capturing detection signals, and a cycle signal input 13.

The first and second semiconductor chip 2, 6 are arranged on a common circuit board 14, which has electric lines 15A, 15B, 15C, 15D structured as conductor tracks, which connect the connectors 4A, 4B, 4C, 4D of the Hall sensor element 3 to connection contacts 10A, 10B, 10C, 10D of the switching device 8.

Aside from the semiconductor chips 2, 6 of the chopped Hall sensor 1A and the electric lines 15A, 15B, 15C, 15D, circuit components for an electronic circuit, not shown in any detail in the drawing, are arranged on the circuit board 14, which circuit can have a user interface with a monitor, for example.

The switching device 8 is configured in such a manner that it connects one connector of one of the two connection pairs 4A, 4B or 4C, 4D of the Hall sensor element 3 to the one supply connector 11A, and the other connector of the connection pair 4A, 4B or 4C, 4D in question to the other supply connector 11B, during each spin Hall phase, for feeding the supply current into the Hall sensor element 3, in each instance.

Furthermore, during each spin Hall phase, for capturing the detection signal, in each instance, a connector of the other connection pair 4C, 4D or 4A, 4B of the Hall sensor element 3 is connected to the one signal connector 12A, and the other connector of this connection pair is connected to the other signal connector 12B. As will still be explained in greater detail below, further switching of the switching device 9 takes place as a function of a cycle signal that is made available by the control device and is applied to the cycle signal input 13 of the switching device 8.

In the exemplary embodiment shown in FIG. 1, the control device 9 has a pulse generator 26 having an oscillator 16, which is connected, by way of a frequency divider 17, to an input connector of a binary frequency generator 18. The oscillator 16 and the frequency divider 17 are configured in such a manner that a cycle signal is output at the output of the frequency divider 17, with a frequency of 1024 kHz.

As can be seen in FIG. 1, the binary frequency generator 18 has multiple frequency divider stages 19 arranged in series, each having an input and an output. The frequency divider stages 19 divide the frequency of the cycle signal that is applied to their input, in each instance, by two, and output a cycle signal having a correspondingly halved frequency at their output.

The input of a first frequency divider stage 19 is connected to an output of the frequency divider 17, the input of a second frequency divider stage 19 is connected to an output of the first frequency divider stage 19, the input of a third frequency divider stage 19 is connected to an output of the second frequency divider stage 19, etc. Using the oscillator 16, the frequency divider 17, and the frequency generator 18, cycle signals having the following frequencies are generated: 1024 kHz, 512 kHz, 256 kHz, 128 kHz, 64 kHz, 32 kHz, 16 kHz, and 8 kHz.

The parameters (maximum frequency, minimum frequency, step width of the frequency change, mode of operation, etc.) for the frequency to be applied at the cycle signal input 13 of the switching device 8 can be adjusted by means of a programming device 25 integrated into the control device 9.

In a first mode of operation of the control device 9, a cycle signal having a different frequency is applied to the cycle signal input 13, in each instance, during every one of eight consecutive spin Hall phases that follow one another, in each instance. This can be done, for example, using a programmable multiplexer, which connects the output of the frequency divider 17 in question or an output of a frequency divider stage 19, in each instance, to the cycle signal input 13.

This can be done, for example, in such a manner that the aforementioned frequencies are run through cyclically. Proceeding from the first to the eighth spin Hall phase, the time period then doubles, in each instance, during which period the supply current flows through the electric lines 15A, 15B or 15C, 15D and the Hall sensor element.

This sequence is repeated during the spin Hall phases 9 to 16, i.e., the cycle frequency at the cycle signal input 13 jumps from 8 kHz in the eighth spin Hall phase to 1024 kHz in the ninth spin Hall phase, and is then cut in half, in each instance, from the 10^{th} to the 16^{th} spin Hall phase. The aforementioned steps can be repeated once or multiple times during further spin Hall phases.

In detail, the following steps occur in the first eight spin Hall phases:

### 1^{st} Spin Hall Phase:

A first cycle signal, having a frequency of 1024 kHz, is applied to the cycle signal input 13.
At the beginning of the cycle period of the cycle of the first cycle signal, the first supply connector 11A is connected to the first connector 4A of the Hall sensor element 3, and the second supply connector 11B is connected to the second connector 4B of the Hall sensor element 3, so as to imprint the supply current onto the Hall sensor element 3 in a first direction.
Furthermore, the first signal connector 12A is connected to the third connector 4C of the Hall sensor element 3, and the second signal connector 12B is connected to the fourth connector 4D of the Hall sensor element 3, so as to capture a first detection signal between the signal connectors 12A, 12B.

### 2^{nd} Spin Hall Phase:

At the end of the cycle period of the cycle of the first cycle signal, a second cycle signal having a frequency of 512 kHz is applied to the cycle signal input 13.
During the cycle period of the cycle of the second cycle signal, the first supply connector 11A is connected to the third connector 4C of the Hall sensor element 3, and the second supply connector 11B is connected to the fourth connector 4D of the Hall sensor element 3, so as to imprint the supply current onto the Hall sensor element 3 in a second direction.
Furthermore, the first signal connector 12A is connected to the first connector 4A of the Hall sensor element 3, and the second signal connector 12B is connected to the second connector 4B of the Hall sensor element 3, so as to capture a second detection signal between the signal connectors 12A, 12B.

3^{rd} Spin Hall Phase:
At the end of the cycle period of the cycle of the second cycle signal, a third cycle signal having a frequency of 256 kHz is applied to the cycle signal input 13.
During the cycle period of the cycle of the third cycle signal, the first supply connector 11A is connected to the second connector 4B of the Hall sensor element 3, and the second supply connector 11B is connected to the first connector 4A of the Hall sensor element 3, so as to imprint the supply currents onto the Hall sensor element 3 in a third direction.
Furthermore, the first signal connector 12A is connected to the fourth connector 4D of the Hall sensor element 3, and the second signal connector 12B is connected to the third connector 4C of the Hall sensor element 3, so as to capture a third detection signal between the signal connectors 12A, 12B.

### 4^{th} Spin Hall Phase:

At the end of the cycle period of the cycle of the third signals, a fourth cycle signal having a frequency of 128 kHz is applied to the cycle signal input 13.
During the cycle period of the cycle of the fourth cycle signal, the first supply connector 11A is connected to the fourth connector 4D of the Hall sensor element 3, and the second supply connector 11B is connected to the third connector 4C of the Hall sensor element 3, so as to imprint the supply current onto the Hall sensor element 3 in a fourth direction.
Furthermore, the first signal connector 12A is connected to the second connector 4B of the Hall sensor element 3, and the second signal connector 12B is connected to the first connector 4A of the Hall sensor element 3, so as to capture a fourth detection signal between the signal connectors 12A, 12B.

### 5^{th} Spin Hall Phase:

At the end of the cycle period of the cycle of the fourth cycle signal, a fifth cycle signal having a frequency of 64 kHz is applied to the cycle signal input 13.
During the cycle period of the cycle of the fifth cycle signal, the first supply connector 11A is connected to the second connector 4B of the Hall sensor element 3, and the second supply connector 11B is connected to the first connector 4A of the Hall sensor element 3, so as to imprint the supply current onto the Hall sensor element 3 in the third direction. In this regard, the direction of rotation of the supply current changes to the opposite direction of that in the second to fourth spin Hall phase.
Furthermore, the first signal connector 12A is connected to the fourth connector 4D of the Hall sensor element 3, and the second signal connector 12B is connected to the third connector 4C of the Hall sensor element 3, so as to capture a fifth detection signal between the signal connectors 12A, 12B.

### 6^{th} Spin Hall Phase:

At the end of the cycle period of the cycle of the fifth cycle signal, a sixth cycle signal having a frequency of 32 kHz is applied to the cycle signal input 13.
During the cycle period of the cycle of the second cycle signal, the first supply connector 11A is connected to the third connector 4C of the Hall sensor element 3, and the second supply connector 11B is connected to the fourth connector 4D of the Hall sensor element 3, so as to imprint the supply current onto the Hall sensor element 3 in the second direction.
Furthermore, the first signal connector 12A is connected to the first connector 4A of the Hall sensor element 3, and the second signal connector 12B is connected to the second connector 4B of the Hall sensor element 3, so as to capture a sixth detection signal between the signal connectors 12A, 12B.

### 7^{th} Spin Hall Phase:

At the end of the cycle period of the cycle of the sixth cycle signal, a seventh cycle signal having a frequency of 16 kHz is applied to the cycle signal input 13.
During the cycle period of the cycle of the seventh cycle signal, the first supply connector 11A is connected to the first connector 4A of the Hall sensor element 3, and the second supply connector 11B is connected to the second connector 4B of the Hall sensor element 3, so as to imprint the supply current onto the Hall sensor element 3 in the first direction.
Furthermore, the first signal connector 12A is connected to the third connector 4C of the Hall sensor element 3, and the second signal connector 12B is connected to the fourth connector 4D of the Hall sensor element 3, so as to capture a seventh detection signal between the signal connectors 12A, 12B.

### 8^{th} Spin Hall Phase:

At the end of the cycle period of the cycle of the seventh cycle signal, an eighth cycle signal having a frequency von 8 kHz is applied to the cycle signal input 13.
During the cycle period of the cycle of the eighth cycle signal, the first supply connector 11A is connected to the fourth connector 4D of the Hall sensor element 3, and the second supply connector 11B is connected to the third connector 4C of the Hall sensor element 3, so as to imprint the supply current onto the Hall sensor element 3 in the fourth direction.
Furthermore, the first signal connector 12A is connected to the second connector 4B of the Hall sensor element 3, and the second signal connector 12B is connected to the first connector 4A of the Hall sensor element 3, so as to capture an eighth detection signal between the signal connectors 12A, 12B.

In a corresponding manner, further spin Hall cycles can be carried out, as necessary, in order to measure further detection signals.

As can be seen in FIG. 1, the signal connectors 12A, 12B of the switching device 8 are connected, by way of a filter 20, to the inputs of a measurement amplifier 21. In the filter, the average is formed from a plurality of detection signals, so as to be able to compensate offset voltages contained in the detection signals.

The filter can also be structured in such a manner that it blocks frequencies of external electromagnetic interference in the surroundings of the Hall sensor element, which do not agree with a frequency of the chopped Hall sensor 1. The power spectrum in FIG. 3 shows an example of the distribution of the frequencies of electromagnetic interference in the surroundings of the Hall sensor element 3 and of frequencies that are generated in a chopped Hall sensor 1A, 1B. In this regard, discrete interference frequencies are shown as dotted arrows, interference frequency bands are shown as cross-hatched columns, and frequencies that are generated in the chopped Hall sensor 1A, 1B are shown as solid arrows. Only one of the frequencies generated in the chopped Hall sensor 1A, 1B interferes with an interference frequency.

In the case of the method having the spin Hall phases described above, the mean value can be formed, for example, from a number of 8 detection signals. The mean value is amplified using the measurement amplifier. In a detection signal processing device that follows the measurement amplifier, a value for the Hall voltage to be measured and/or for the magnetic flow density in the Hall voltage sensor 3 is determined from the mean value.

In a second mode of operation of the control device 9, as well, a cycle signal having a different frequency, in each instance, is applied at the cycle signal input 13 during each of eight spin Hall phases of a spin Hall cycle that occur one after the other, in each instance. For this purpose, the control device 9 has a pseudo-random generator 22, which stands in a control connection with a frequency control input 23 of the pulse generator 26, for randomly changing the cycle frequency of the pulse generator 26.

In contrast to the first mode of operation, however, the frequency at the cycle signal input 13 is not cut in half from spin Hall cycle to spin Hall cycle, in each instance, but rather the new frequency value is selected from the available frequencies, in a random or quasi-random manner, for example in the following sequence: 512 kHz, 8 kHz, 256 kHz, 64 kHz, 32 kHz, 1024 kHz, 128 kHz, 16 kHz.

The chopped Hall sensor 1A shown in FIG. 1 can also be operated in such a manner that the cycle period is kept constant during a spin Hall cycle having 8 spin Hall phases, in each instance, and is only changed after the end of the spin Hall cycle, so as to carry out a further spin Hall cycle with the changed cycle period.

It should also be mentioned that in the case of the chopped Hall sensor 1A, a spin Hall cycle can also have only four phases. In this case, the supply current in the Hall sensor element 3 is only rotated in one direction of rotation.

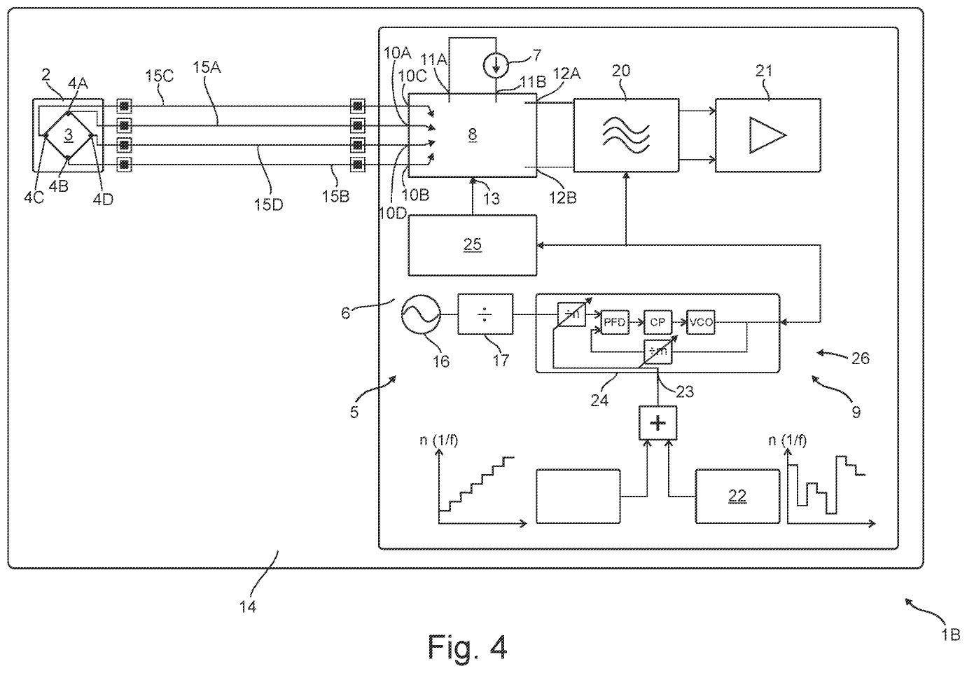

In the chopped Hall sensor 1B shown in FIG. 4, the control device 9 has a frequency synthesizer 24 for generating the cycle signal. An oscillator 16 is connected to the input of the frequency synthesizer 24 by way of a frequency divider 17. The frequency synthesizer 24 has an adjustable phase control circuit (PLL—phase-locked loop), in a known manner, in which circuit a voltage-controlled oscillator (VCO) is arranged. The output of the frequency synthesizer 24 is connected to the cycle signal input 13 of the switching device 8.

For the remainder, the chopped Hall sensor 1B shown in FIG. 4 essentially corresponds to the chopped Hall sensor 1A from FIG. 1, so that the description of the chopped Hall sensor 1A applies accordingly to the chopped Hall sensor 1B.

1. A method for measuring at least one Hall voltage, in which method at least one Hall sensor element is made available, which element comprises a plurality of connection pairs for imprinting a supply current or applying a supply voltage and for capturing detection signals, wherein the method has the following steps:
a) imprinting the supply current onto the Hall sensor element or applying the supply voltage to the Hall sensor element, in such a manner that the supply current flows from the first to the second connector of one of the connection pairs for a predetermined period of time;
b) while imprinting the supply current or applying the supply voltage, capturing a detection signal between the first and the second connector of a further connection pair of the Hall sensor element;
c) repeating steps a) and b) once or multiple times, using connection pairs and/or connectors that are interchanged according to an orthogonal switching principle or a spin current principle, once or multiple times, so as to capture at least one further detection signal,
d) determining the Hall voltage from the detection signals,
wherein in at least one of the repetitions mentioned in step c), the predetermined time period is changed, and the steps mentioned in step c) are repeated with the changed time period.

2. A method for measuring at least one Hall voltage, in which method at least one Hall sensor element is made available, which element comprises a plurality of connection pairs for imprinting a supply current or applying a supply voltage and for capturing detection signals, wherein the method has the following steps:
a) imprinting the supply current onto the Hall sensor element or applying the supply voltage to the Hall sensor element, in such a manner that the supply current flows from the first to the second connector of one of the connection pairs for a predetermined period of time;
b) while imprinting the supply current or applying the supply voltage, capturing a detection signal between the first and the second connector of a further connection pair of the Hall sensor element;
c) repeating steps a) and b) once or multiple times, using connection pairs and/or connectors that are interchanged according to an orthogonal switching principle or a spin current principle, once or multiple times, so as to capture at least one further detection signal,
d) determining the Hall voltage from the detection signals,
e) repeating steps a) to d) and, if applicable, e),
wherein in step e), the predetermined time period is changed, and the steps mentioned in step e) are repeated with the changed time period.

3. The method according to claim 1, wherein the Hall sensor element is arranged in an environment in which at least one electromagnetic signal is present, which has at least one discrete interference frequency that causes electromagnetic interference at the detection signals, and/or comprises at least one frequency band that causes electromagnetic interference at the detection signals.

4. The method according to claim 1, wherein a cycle signal is generated and the predetermined time period is set as a function of the period duration of the cycle signal.

5. The method according to claim 4, wherein to change the predetermined time period, the frequency of the cycle signal is divided by a whole number, in particular by 2ⁿ, wherein n is a whole number that is greater than 1.

6. The method according to claim 4, wherein the cycle signal is generated by means of a frequency synthesizer.

7. The method according to claim 1, wherein the frequency of the cycle signal for changing the predetermined time period is increased or reduced, in each instance, by a predetermined step width, in such a manner that the frequency of the cycle signal does not exceed a predetermined maximum value and does not drop below a predetermined minimum value.

8. The method according to claim 1, wherein a random signal is generated and the frequency of the cycle signal for changing the predetermined time period is changed as a function of the random signal, in such a manner that the frequency of the cycle signal does not exceed a predetermined maximum value and does not drop below a predetermined minimum value.

9. A chopped Hall sensor having at least one Hall sensor element that has a plurality of connection pairs for imprinting a supply current and for capturing detection signals, and having a control and evaluation apparatus for the Hall sensor element, which has
at least one current or voltage supply source for generating the supply current,
a switching device, and
a control device that has a pulse generator, for the switching device,
wherein the switching device has
connection contact pairs that are connected to the connection pairs of the Hall sensor element by way of electric lines,
supply connectors that are connected to the current or voltage supply source, and
signal connectors for capturing the detection signals,
and wherein the switching device, the control device, and the pulse generator are configured for carrying out the following steps:
a) for a predetermined time period, connecting a connection pair of the Hall sensor element to the supply connectors, so as to imprint a supply current onto the Hall sensor element, which current flows from the first to the second connector of the connection pair,
b) connecting a further connection pair of the Hall sensor element to the signal connectors, so as to capture a detection signal present between the first and the second connector of the further connection pair while imprinting the supply current onto the Hall sensor element;
c) repeating steps a) and b) once or multiple times, using connection pairs and/or connectors that are interchanged according to an orthogonal switching principle or a spin current principle, once or multiple times, so as to capture at least one further detection signal, and
d) determining the Hall voltage from the detection signals,
wherein the switching device, the control device and the pulse generator are configured in such a manner that during at least one of the repetitions mentioned in step c), the predetermined time period is changed and used during repetition of steps a) and b).

10. A chopped Hall sensor having at least one Hall sensor element that has a plurality of connection pairs for imprinting a supply current and for capturing detection signals, and having a control and evaluation apparatus for the Hall sensor element, which has
at least one current or voltage supply source for generating the supply current,
a switching device, and
a control device that has a pulse generator, for the switching device,
wherein the switching device has
connection contact pairs that are connected to the connection pairs of the Hall sensor element by way of electric lines,
supply connectors that are connected to the current or voltage supply source, and
signal connectors for capturing the detection signals,
and wherein the switching device, the control device, and the pulse generator are configured for carrying out the following steps:
a) for a predetermined time period, connecting a connection pair of the Hall sensor element to the supply connectors, so as to imprint a supply current onto the Hall sensor element, which current flows from the first to the second connector of the connection pair,
b) connecting a further connection pair of the Hall sensor element to the signal connectors, so as to capture a detection signal present between the first and the second connector of the further connection pair while imprinting the supply current onto the Hall sensor element;
c) repeating steps a) and b) once or multiple times, using connection pairs and/or connectors that are interchanged according to an orthogonal switching principle or a spin current principle, once or multiple times, so as to capture at least one further detection signal, and
d) determining the Hall voltage from the detection signals;
e) repeating steps a) to d) and, if applicable, e),
wherein the switching device, the control device and the pulse generator are configured with the changed time period for changing the predetermined time period in step e) and for repeating the steps mentioned in step e).

11. The chopped Hall sensor according to claim 9, wherein at least one Hall sensor element is integrated into a first semiconductor chip, and the control and evaluation apparatus is integrated into a second semiconductor chip.

12. The chopped Hall sensor according to claim 9, wherein the signal connectors are connected to the inputs of a measurement amplifier by way of a filter, and that the filter is structured for blocking at least one discrete frequency and/or at least one frequency band.

13. The chopped Hall sensor according to claim 9, wherein the pulse generator has a frequency synthesizer.

14. The chopped Hall sensor according to claim 9, wherein the control device has a random generator or a pseudo-random generator that stands in a control connection with a frequency control input of the pulse generator, for randomly changing the cycle frequency of the pulse generator.

15. The chopped Hall sensor according to claim 9, wherein the control device has an output for a control signal, which output stands in a control connection with a frequency control input of the pulse generator, to change the cycle frequency of the pulse generator.
